(19) United States
(12) Patent Application Publication
(10) Pub. No.: US 2026/0257479 A1
(43) Pub. Date: Sep. 3, 2026

(54) INKJET PRINTING APPARATUS INCLUDING CLEANING HEAD AND METHOD OF CLEANING INKJET PRINTING APPARATUS

(71) Applicant: SAMSUNG DISPLAY CO., LTD., YONGIN-SI (KR)

(72) Inventor: Futoshi YOSHIDA, Yokohama-shi, Kanagawa (JP)

(21) Appl. No.: 19/455,037

(22) Filed: Jan. 21, 2026

(30) Foreign Application Priority Data
Feb. 28, 2025 (JP) 2025-031266

(51) Int. Cl. B41J 2/165; B41J 3/28; B41J 3/54; B41J 11/00; B41J 11/06; B41J 29/02; H10K 71/13

(52) U.S. Cl. CPC B41J 2/16508; B41J 3/28; B41J 3/543; B41J 11/00244; B41J 11/06; B41J 29/02; H10K 71/135

(57) ABSTRACT

An inkjet printing apparatus includes a first stage, a second stage which is disposed on the first stage and in which a substrate including a print area is disposed, a head assembly moving in a first direction and including a housing disposed on the substrate, a plurality of print heads arranged inside the housing, a plurality of nozzles arranged inside the print heads, and an inkjet supply device that supplies an ink to the print heads, a cleaning assembly disposed on the first stage and moving in a second direction intersecting the first direction, and a cleaning head which is disposed on the cleaning assembly, in which a plurality of recesses at least partially overlapping the nozzles are defined when viewed on a plane, which includes a hygroscopic material, and which moves in the first direction and the second direction.

### CROSS-REFERENCE TO RELATED APPLICATION

This U.S. non-provisional patent application claims priority under 35 U.S.C. § 119 to Japanese Patent Application No. 2025-031266 filed on February 28, 2025, in the Japan Patent Office, the disclosures of which are incorporated by reference herein in their entireties.

### TECHNICAL FIELD

Embodiments of the present disclosure relate to an inkjet printing apparatus and, more particularly to, an inkj et printing apparatus including a cleaning head and a method of cleaning an inkjet printing apparatus.

### DISCUSSION OF THE RELATED ART

In general, an organic light emitting diode (OLED) display, which exhibits good luminance characteristics, wide view-angle characteristics, and self-emission capability that eliminates the need for a separate light source unit, is recognized as a next-generation flat-panel display technology. Because the OLED display device emits light through its own organic light-emitting elements, the OLED display device may be manufactured in a lightweight and thin structure. As a result, the OLED display has characteristics such as low power consumption, a high luminance, and an efficient or fast response time.

The OLED display includes a plurality of light emitting elements each including an anode, an organic light emitting layer, and a cathode. Holes and electrons are injected into the organic light emitting layer from the anode and the cathode to form excitons, and as the excitons transition to the ground state, the light emitting element emits light.

During fabrication of each light emitting element, the organic light emitting layer may be deposited or patterned using an inkjet printing apparatus. The inkjet printing apparatus may discharge an organic material composition (or an ink) onto the substrate through one or more nozzles to form the organic light emitting layer. When manufacturing the OLED display device, a precise, high-resolution patterning process of the organic light-emitting material is required to achieve uniform emission and pixel definition. As a pixel size decreases in high-resolution OLED display, the inkjet printing apparatus need to discharge a proportionally smaller amount of the ink.

When the amount of the ink discharged from the inkjet printing apparatus is not finely controlled, a defective organic light emitting layer may be manufactured. Therefore, there is a need for an inkjet printing apparatus and associated cleaning and control techniques that enable fine and stable control of ink discharge characteristics.

### SUMMARY

Embodiments of the present disclosure provide an inkjet printing apparatus capable of reducing a defect ratio of an organic light emitting layer.

Embodiments of the present disclosure also provide a method of cleaning an inkjet printing apparatus capable of reducing a defect ratio of an organic light emitting layer.

According to an embodiment, an inkjet printing apparatus includes a first stage, a second stage including a heater disposed on the first stage, where the second stage is configured to support a substrate including a print area overlapping the heater, a head assembly disposed over the substrate, where the head assembly is configured to move in a first direction parallel to an upper surface of the first stage and includes a housing, a plurality of print heads disposed inside the housing, a plurality of nozzles disposed on lower surfaces of the plurality of print heads, respectively, and an inkjet supply device that supplies an ink to the plurality of print heads, a cleaning assembly disposed on the first stage and configured to move in a second direction intersecting the first direction, and cleaning assembly includes a cleaning head including a hygroscopic material and configured to move in the first direction and the second direction, and including a plurality of recesses at least partially overlapping the nozzles.

The nozzles may include a plurality of first nozzles formed as a first nozzle group and spaced apart in the first direction, a plurality of second nozzles formed as a second nozzle group and spaced apart in the first direction, and a plurality of third nozzles formed as a third nozzle group and spaced apart in the first direction.

The first nozzle group, the second nozzle group, and the third nozzle group may be spaced apart in the second direction.

The first nozzles and the third nozzles may be arranged in same columns in the second direction.

The first nozzles, the second nozzles, and the third nozzles may be arranged in a zigzag pattern.

The cleaning head may include a first cleaning head portion overlapping the first nozzles, the third nozzles, and the recesses.

The cleaning head may include a second cleaning head portion overlapping the second nozzles and the recesses.

The second stage may further include an adsorption hole.

The inkjet printing apparatus may further include a first frame connecting the first stage and the head assembly.

The inkjet printing apparatus may further include a second frame disposed on the cleaning assembly and connecting the cleaning assembly and the cleaning head.

According to an embodiment, a method for cleaning an inkjet printing apparatus includes preparing a first stage, disposing a second stage including a heater on the first stage, disposing a substrate including a print area overlapping the heater on the second stage, disposing a head assembly including a plurality of nozzles on the substrate, discharging an ink onto the substrate through the plurality of nozzles, arranging a cleaning head adjacent to lower surfaces of the plurality of nozzles, and absorbing the ink remaining in the nozzles through the cleaning head.

The head assembly may be configured to move in a first direction parallel to an upper surface of the first stage, the head assembly may further include a housing, a plurality of print heads disposed inside the housing, and an ink supply device that supplies the ink to the plurality of print heads, and the nozzles may be arranged inside the plurality of print heads, respectively.

In one aspect, arranging the cleaning head may include arranging the cleaning head adjacent to the lower surfaces of the nozzles by moving the cleaning head in a first direction, a second direction intersecting the first direction, and a third direction intersecting a plane defined by the first direction and the second direction.

The method may further include disposing a cleaning assembly configured to move the cleaning head in the first direction and the second direction under the cleaning head.

The cleaning head may include a hygroscopic material, and may include a plurality of recesses overlapping portions the nozzles.

The method may further include positioning the cleaning head into contact with the ink remaining on the nozzles.

The nozzles may include a plurality of first nozzles formed as a first nozzle group and spaced apart in a first direction, a plurality of second nozzles formed as a second nozzle group and spaced apart in the first direction, and a plurality of third nozzles formed as a third nozzle group and spaced apart in the first direction, and the first nozzle group, the second nozzle group, and the third nozzle group may be spaced apart in a second direction intersecting the first direction.

The cleaning head may include a first cleaning head portion disposed adjacent to lower surfaces of the first nozzles and the third nozzles and absorbs an ink remaining on the first nozzles and the third nozzles and a second cleaning head portion disposed adjacent to lower surfaces of the second nozzles and absorbs an ink remaining on the second nozzles.

An electronic device including a display device including a pixel manufactured using an inkj et printing apparatus, and a processor configured to transmit an image data signal and an input control signal to the display device. The the inkjet printing apparatus includes a first stage, a second stage including a heater disposed on the first stage, where the second stage is configured to support a substrate including a print area overlapping the heater, a head assembly disposed over the substrate, wherein the head assembly is configured to move in a first direction parallel to an upper surface of the first stage and includes a housing, a plurality of print heads disposed inside the housing, a plurality of nozzles disposed inside the plurality of print heads, respectively, and an inkjet supply device configured to supply an ink to the plurality of print heads, and a cleaning assembly disposed on the first stage and configured to move in a second direction intersecting the first direction. The cleaning assembly includes a cleaning head including a hygroscopic material and configured to move in the first direction and the second direction, and including a plurality of recesses at least partially overlapping the nozzles.

In one aspect, the nozzles include a plurality of first nozzles formed as a first nozzle group and spaced apart in the first direction, a plurality of second nozzles formed as a second nozzle group and spaced apart in the first direction, and a plurality of third nozzles formed as a third nozzle group and spaced apart in the first direction. The first nozzles, the second nozzles, and the third nozzles are arranged in a zigzag pattern.

### BRIEF DESCRIPTION OF THE FIGURES

Embodiments and features of the present disclosure are apparent from the detailed description with reference to the accompanying drawings.

FIG. 1 is a block diagram of an electronic device according to an embodiment of the present disclosure.

FIG. 2 illustrates schematic views of electronic devices according to an embodiment of the present disclosure.

FIG. 3 is a view illustrating a method for forming an organic light emitting layer using an inkjet printing apparatus.

FIG. 4 is a view illustrating a cross-section of a pixel illustrated in FIG. 3.

FIG. 5A is a perspective view of the inkjet printing apparatus according to an embodiment of the present disclosure.

FIG. 5B is a cross-sectional view along line I-I' of FIG. 5A.

FIG. 6 is a schematic perspective view illustrating a head assembly according to an embodiment of the present disclosure.

FIGS. 7A and 7B are plan views of the inkjet printing apparatus according to an embodiment of the present disclosure.

FIGS. 8A, 8B, and 8C are cross-sectional views of the head assembly and a cleaning head according to an embodiment of the present disclosure.

FIGS. 9A, 9B, 9C, 9D, 9E, and 9F are schematic cross-sectional views illustrating a method for cleaning an inkjet printing apparatus according to an embodiment of the present disclosure.

### DETAILED DESCRIPTION

new paragraph...

As described in the specification, the expression that a first component (or area, layer, part, portion, etc.) is "disposed on", "connected with" or "coupled to" a second component may represent that the first component is directly disposed on/connected with/coupled to the second component or may represent that a third component is interposed therebetween.

The same reference numerals/symbols may be used to indicate the same components. Further, in the drawings, the thickness, the ratio, and the dimension of components are exaggerated for effective description of technical contents. For example, while each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like. The expression "and/or" includes one or more combinations of the associated components.

Although the terms "first," "second," etc., may be used to describe various components, the components should not be limited by the terms. The terms are used to distinguish one component, one part, one area, one layer or one portion from another component, another part, another area, another layer or another portion. For example, without departing from the scope of the present disclosure, a first component, a first part, a first area, a first layer, or a first portion may be referred to as a second component, a second part, a second area, a second layer, or a second portion, and similarly, the second component, the second part, the second area, the second layer, or the second portion may also be referred to as the first component, the first part, the first area, the first layer, or the first portion. Singular expressions include plural expressions unless clearly otherwise indicated in the context.

Also, the terms "under", "below", "on", "above", etc. are used to describe the correlation of components illustrated in drawings. The terms that are relative in concept are described based on a direction illustrated in drawings.

It will be understood that the terms "include", "comprise", "have", etc. describe the presence of features, numbers, steps, operations, elements, or components, described in the specification, or a combination thereof, and do not exclude the presence or additional possibility of one or more other features, numbers, steps, operations, elements, or components or a combination thereof.

Unless otherwise defined, all terms (including technical terms and scientific terms) used in the specification have the same meaning as commonly understood by those skilled in the art to which the present disclosure belongs.

Hereinafter, an embodiment of the present disclosure is described with reference to the accompanying drawings.

Embodiments of the present disclosure provide an inkjet printing apparatus and a method for cleaning the inkjet printing apparatus. The inkjet printing apparatus includes a head assembly configured to discharge ink through a plurality of nozzles, a multi-stage platform including a first stage and a second stage having an integrated heater, and a cleaning assembly having a cleaning head and hygroscopic recesses. The cleaning head is movably supported by a frame structure such that the cleaning head is configured to move in first, second, and third directions to align with the nozzles. During a cleaning operation, residual ink present at the discharge portions of the nozzles is absorbed into the hygroscopic recesses through non-contact mechanism, while the cleaning head reciprocates and moves under the nozzles of the head assembly. Accordingly, the inkjet printing apparatus can effectively remove dried ink, maintain nozzle cleanliness, and prevent clogging without damaging the discharge surface, thereby improving ejection stability and printing uniformity.

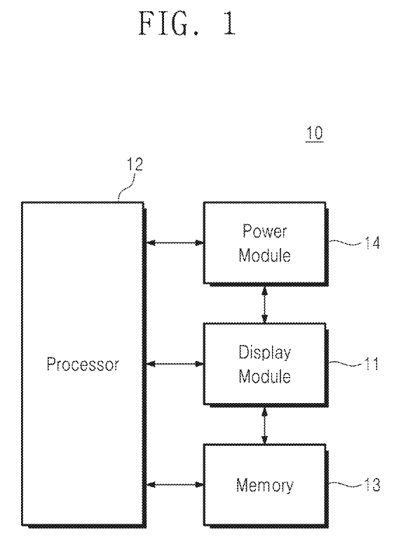

FIG. 1 is a block diagram of an electronic device according to an embodiment of the present disclosure.

Referring to FIG. 1, an electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information for operating the processor 12 or the display module 11. When the processor 12 executes an application stored in the memory 13, an image data signal and/or an input control signal may be transmitted to the display module 11, and the display module 11 may process the received signal and output image information through a display screen in the display module 11.

The power module 14 may include a power supply module such as a power adapter or a battery device and a power conversion module that converts power supplied from the power supply module to power for operating the electronic device 10.

At least one of the components of the electronic device 10 may be included in the display device according to an embodiment. Further, some of individual modules may be included inside the display device as a single module, and the others modules may be provided separately from the display device. For example, the display device may include the display module 11, and the processor 12, the memory 13, and the power module 14 may be provided in the form of other devices in the electronic device 10 rather than the display device.

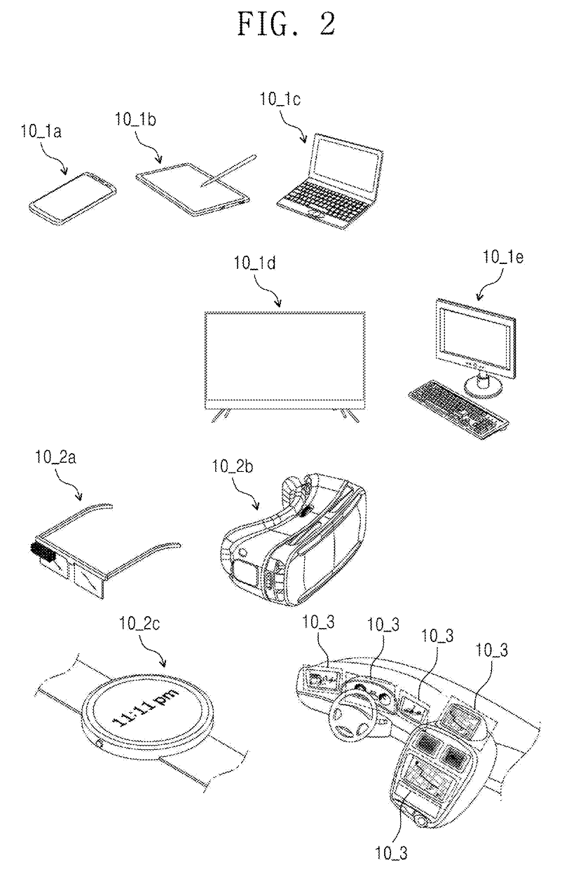

FIG. 2 illustrates schematic views of electronic devices according to an embodiment of the present disclosure.

Referring to FIG. 2, various electronic devices to which the display device is applied may include an image display electronic device such as a smartphone 10_1a, a tablet computer 10_1b, a laptop computer 10_1c, a television (TV) 10_1d, and a desk monitor 10_1e. In some cases, the display device may be implemented in a wearable electronic device including a display module such as a smart glasses 10_2a, a head mounted display 10_2b, and a smart watch 10_2c. In some cases, the display device may be implemented in a vehicle electronic device 10_3 including a display module such as an instrument panel, a center fascia, a center information display (CID) disposed on a dashboard, and a room mirror display of a vehicle.

The electronic device 10 may include a display device that displays an image and a processor that processes an image signal and provides the image signal to the display device. The display device may include a pixel manufactured by a method of cleaning an inkjet printing apparatus which will be described below. In some cases, the display device may include a pixel manufactured using the inkjet printing apparatus.

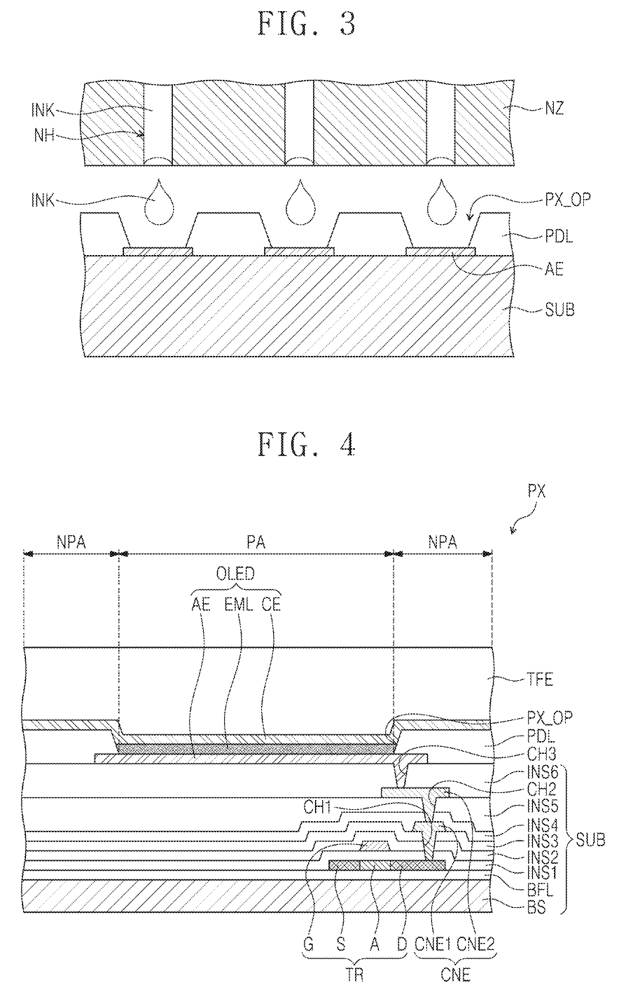

FIG. 3 is a view illustrating a method for forming an organic light emitting layer using an inkjet printing apparatus. FIG. 4 is a view illustrating a cross-section of a pixel illustrated in FIG. 3.

For the convenience of description, FIG. 3 illustrates a cross section of nozzles NZ in which three nozzle holes NH are included in the inkj et printing apparatus. However, the number of nozzle holes NH are not necessarily limited thereto.

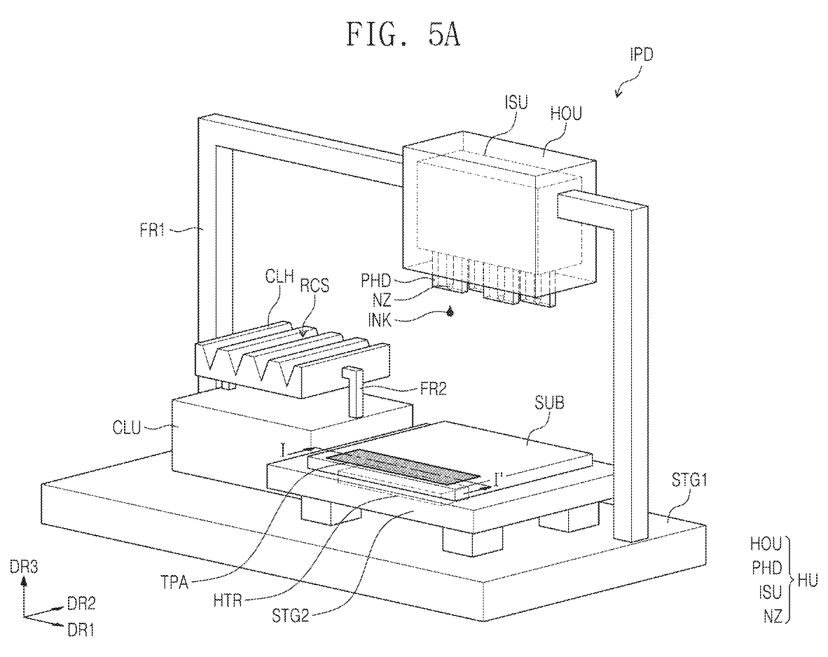

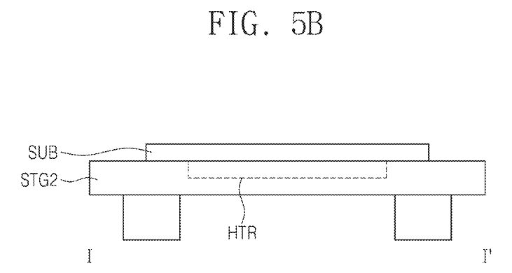

Referring to FIGS. 3 and 4, an inkjet printing apparatus IPD (see FIG. 5A) may be used to form a light emitting layer EML. For example, each pixel PX may include a transistor TR and a light emitting element OLED connected to the transistor TR. In one aspect, the transistor TR may serve as a driving element. For example, one pixel PX may be illustrated. In some cases, a plurality of pixels PX may be arranged on a base layer BS.

The light emitting element OLED may include a first electrode AE, a second electrode CE, and the light emitting layer EML disposed between the first electrode AE and the second electrode CE. The first electrode AE may be an anode electrode, and the second electrode CE may be a cathode electrode.

The transistor TR and the light emitting element OLED may be arranged on the base layer BS. A planar region of the base layer BS may be divided into a light emitting part PA and a non-light emitting part NPA adjacent to or surrounding the light emitting part PA. The light emitting element OLED may be disposed on the light emitting part PA.

A buffer layer BFL may be disposed on the base layer BS, and the buffer layer BFL may be an inorganic layer. In some cases, the buffer layer BFL may include one or more inorganic insulating layers configured to planarize the surface of the base layer BS.

Semiconductor patterns "S," "A," and "D" may be arranged on the buffer layer BFL. The semiconductor patterns "S," "A," and "D" may include polysilicon. However, the present disclosure is not necessarily limited thereto, and the semiconductor patterns "S," "A," and "D" may include amorphous silicon or a metal oxide. In some cases, the semiconductor patterns "S," "A," and "D" may be sequentially arranged on the buffer layer BFL. In some cases, the semiconductor patterns "S," "A," and "D" may be in the same level.

The semiconductor patterns "S," "A," and "D" may be doped with an N-type dopant or a P-type dopant. The semiconductor patterns "S," "A," and "D" may include a high-doped area and a low-doped area. Conductivity of the high-doped area may be higher than the conductivity of the low-doped area, and the high-doped area may substantially serve as a source electrode and a drain electrode of the transistor TR. The low-doped area may substantially correspond to an active area (or a channel) of the transistor.

The source area "S", the active area "A", and the drain area "D" of the transistor TR may be formed from the semiconductor patterns "S," "A," and "D." A first insulating layer INS1 may be disposed on the semiconductor patterns "S," "A," and "D." In some cases, the first insulating layer INS 1 may cover the upper surface of the semiconductor patterns "S," "A," and "D", and the buffer layer BFL. A gate electrode "G" of the transistor TR may be disposed on the first insulating layer INS 1. A second insulating layer INS2 may be disposed on the gate electrode "G." For example, the second insulating layer INS2 may cover an upper surface of the gate electrode "G" and the upper surface of the first insulating layer INS 1. A third insulating layer INS3 may be disposed on the second insulating layer INS2.

A connection electrode CNE may be disposed between the transistor TR and the light emitting element OLED to connect the transistor TR and the light emitting element OLED. The connection electrode CNE may include a first connection electrode CNE1 and a second connection electrode CNE2 that are electrically coupled to each other through a multilayer interconnection structure.

The first connection electrode CNE1 may be disposed on the third insulating layer INS3 and may be connected to the drain area "D" through a first contact hole CH1 penetrating the first insulating layer INS1, the second insulating layer INS2, and the third insulating layer INS3. A fourth insulating layer INS4 may be disposed on the first connection electrode CNE1. A fifth insulating layer INS5 may be disposed on the fourth insulating layer INS4.

The second connection electrode CNE2 may be disposed on the fifth insulating layer INS5. The second connection electrode CNE2 may be connected to the first connection electrode CNE1 through a second contact hole CH2 penetrating the fifth insulating layer INS5. A sixth insulating layer INS6 may be disposed on the second connection electrode CNE2. The first insulating layer INS1 to the sixth insulating layer INS6 may be inorganic layers or organic layers. In some embodiments, each of the insulating layers INS1 to INS6 may include an inorganic insulating material, such as silicon oxide (SiOx), silicon nitride (SiNx), or silicon oxynitride (SiON), or an organic insulating material, such as a polymeric resin.

The first electrode AE may be disposed on the sixth insulating layer INS6. The first electrode AE may be electrically connected to the second connection electrode CNE2 through a third contact hole CH3 penetrating the sixth insulating layer INS6. A pixel defining film PDL, through which a predetermined portion of the first electrode AE is exposed, may be disposed on the first electrode AE and the sixth insulating layer INS6. For example, the pixel defining film PDL may overlap an end portion of the first electrode AE and the sixth insulating layer INS6. A pixel opening PX_OP, through which a predetermined portion of the first electrode AE is exposed, may be formed in the pixel defining film PDL. The pixel defining film PDL may function to electrically insulate adjacent pixel electrodes and to define an emission region for subsequent deposition of the light-emitting material.

The light emitting layer EML may be disposed on the first electrode AE. The light emitting layer EML may be disposed in an area corresponding to the pixel opening PX_OP. The light emitting layer EML may include an organic material and/or an inorganic material. The light emitting layer EML may generate a light having one of red, green, and blue color. In some cases, the light emitting layer EML may generate a light having a white color. In some embodiments, the light-emitting layer EML may include one or more sub-layers, such as a hole injection layer, a hole transport layer, an emission layer, an electron transport layer, and an electron inj ection layer sequentially stacked.

The second electrode CE may be disposed on the light emitting layer EML. The second electrode CE may be commonly disposed in the pixels PX. In some cases, the second electrode CE may cover the pixel defining film PDL and the light emitting layer EML.

A thin film encapsulation layer TFE may be disposed on the light emitting element OLED. The thin film encapsulation layer TFE may be disposed on the second electrode CE to cover the pixel PX. The thin film encapsulation layer TFE may include at least two inorganic layers and an organic layer between the inorganic layers. The inorganic layers may protect the pixel PX from moisture/oxygen. The organic layer may protect the pixel PX from foreign substances such as dust particles.

During operation of the display device including the pixel PX, a first voltage may be applied to the first electrode AE through the transistor TR, and a second voltage having a voltage level lower than that of the first voltage may be applied to the second electrode CE. Holes and electrons injected into the light emitting layer EML are coupled to each other to form excitons, and as the excitons transition to a ground state, the light emitting element OLED may emit visible light.

FIG. 5A is a perspective view of the inkjet printing apparatus according to an embodiment of the present disclosure. FIG. 5B is a cross-sectional view along line I-I' of FIG. 5A.

Referring to FIGS. 5A and 5B, the inkjet printing apparatus IPD may include a first stage STG1, a second stage STG2, a head assembly HU, a cleaning assembly CLU, and a cleaning head CLH. In one aspect, the head assembly HU includes a housing HOU, print heads PHD, an ink supply device ISU, and nozzles NZ.

The second stage STG2 may include a heater HTR and a substrate SUB. The second stage STG2 may be disposed on the first stage STG1. The heater HTR may be disposed within the second stage STG2. For example, as shown in FIG. 5B, an upper surface of the heater HTR may be at a same level as an upper surface of the second stage STG2. In some cases, the second stage STG2 is configured to accommodate (e.g., hold, affix, or secure) the substrate SUB.

The heater HTR may dry ink INK ejected onto the substrate SUB by applying heat (e.g., controlled heat) to the ink INK (see FIG. 3 For example, the ink INK may be applied to a print area TPA, and the ink INK may be dried by the heater HTR. In some cases, the heater HTR may uniformly heat a print area TPA of the substrate SUB.

An adsorption hole may be defined in the second stage STG2. The substrate SUB may be adsorbed and fixed onto the second stage STG2 through the adsorption hole of the second stage STG2. The substrate SUB may include the print area TPA that at least partially overlaps the heater (HTR) in a plan view.

The substrate SUB may move in a second direction DR2 in the second stage STG2. In one aspect, the second direction DR2 may be substantially parallel to an upper surface of the first stage STG1. For example, while the substrate SUB moves in the second direction DR2, the head assembly HU may move relative to the substrate SUB in the second direction DR2 on the second stage STG2.

The head assembly HU may discharge the ink INK to the substrate SUB. The light emitting layer EML (see FIG. 4) may be formed by curing the ink INK discharged from the head assembly HU. For example, the discharged ink INK may subsequently be dried or cured to form the light-emitting layer EML.

The inkjet printing apparatus IPD may include the cleaning assembly CLU disposed on the first stage STG1 and moves in the second direction DR2. The cleaning assembly CLU may clean the nozzles NZ of print heads PHD while moving in the second direction DR2. The head assembly HU may be disposed on and spaced apart from the cleaning assembly CLU, the cleaning assembly CLU may move in the second direction DR2, the head assembly HU may move in a first direction DR1, and thus the nozzles NZ may be cleaned. In some cases, the first direction DR1 may cross (or perpendicular to) the second direction DR2.

The cleaning head CLH may be disposed on the cleaning assembly CLU. A plurality of recesses RCS of which at least portions overlap the nozzles NZ may be defined in the cleaning head CLH in the plan view. The recesses RCS may include a hygroscopic material. In some cases, the hygroscopic material may absorb residual solvent or ink from the nozzle openings during the cleaning operation to maintain discharge stability.

The inkjet printing apparatus IPD may further include a first frame FR1 that connects the first stage STG1 and the head assembly HU. The inkjet printing apparatus IPD may further include a second frame FR2 that connects the cleaning assembly CLU and the cleaning head CLH. The second frame FR2 may be disposed on the cleaning assembly CLU. The cleaning head CLH may move in the first direction DR1, the second direction DR2, and a third direction DR3 through the second frame FR2. For example, the cleaning head CLH may be movably supported by the second frame FR2 so as to move along the first direction DR1, the second direction DR2, and a third direction DR3 perpendicular to a plane formed by the first and second directions DR1 and DR2. In some embodiments, one or more actuators or motors may be mechanically coupled to the second frame FR2 to generate linear or rotational motion that precisely positions the cleaning head CLH in the desired direction. For example, a stepper motor or a linear actuator may be mounted to the second frame FR2 to drive the cleaning head CLH along the first and second directions DR1 and DR2, while an elevation motor or an actuator may adjust vertical positioning along the third direction DR3.

According to embodiments of the present disclosure, the inkjet printing apparatus IPD includes a multi-stage structure in which the substrate SUB and heater HTR are disposed on the second stage STG2 for controlled drying, the head assembly HU is configured to perform precise ink ejection, and the cleaning assembly CLU including the cleaning head CLH, which is configured to remove residual ink and maintain nozzle cleanliness. This inkjet printing apparatus IPD enables stable ink discharge and uniform layer formation by preventing nozzle clogging and ensuring consistent droplet ejection characteristics, thereby improving printing accuracy and yield in high-resolution OLED display manufacturing.

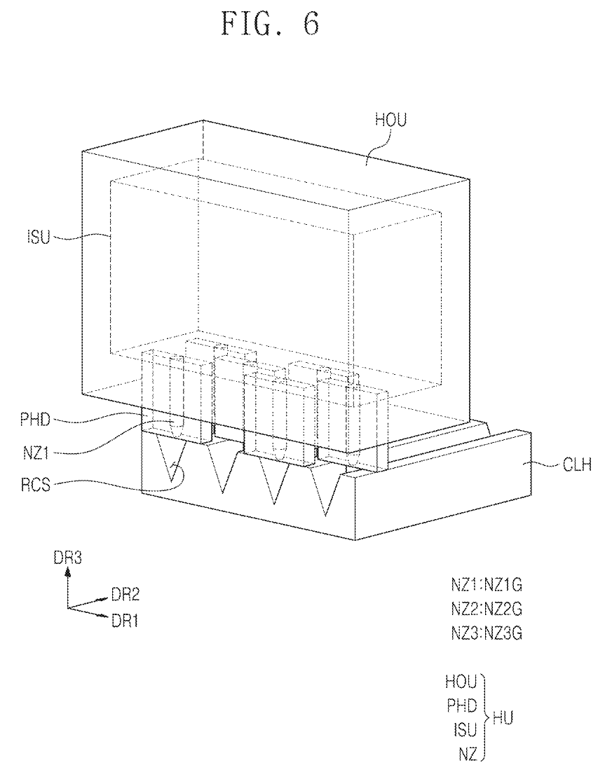

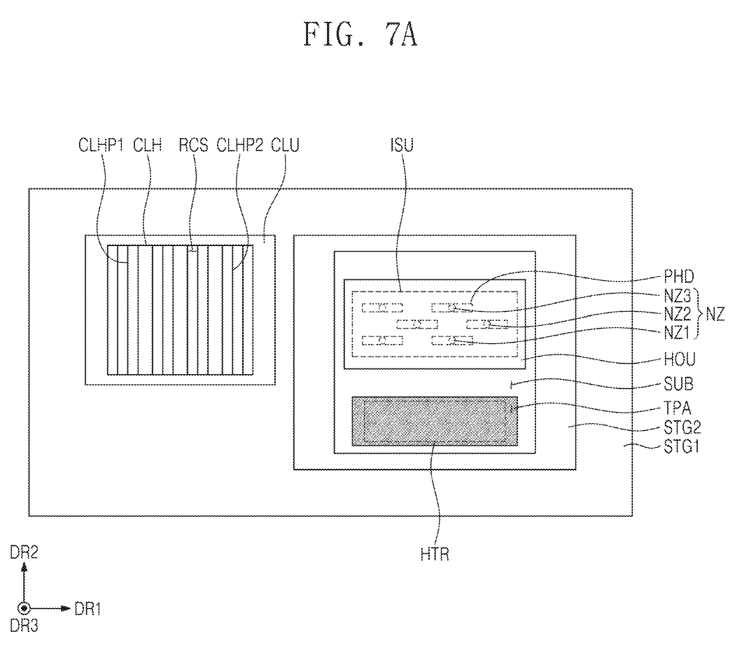

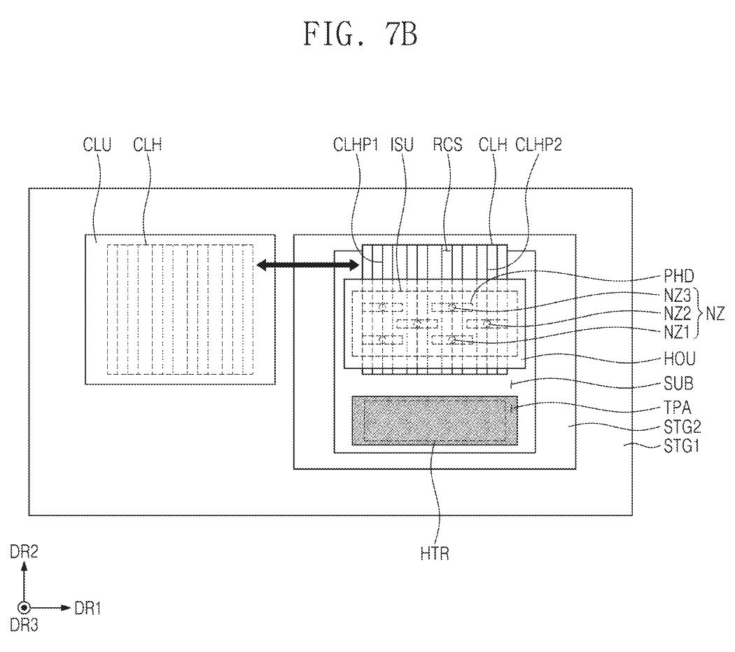

FIG. 6 is a schematic perspective view illustrating a head assembly according to an embodiment of the present disclosure. FIGS. 7A and 7B are plan views of the inkjet printing apparatus according to an embodiment of the present disclosure.

For convenience of description, in FIGS. 7A and 7B, the first frame FR1 and the second frame FR2 might not be shown.

Referring to FIGS. 6, 7A, and 7B, the head assembly HU may include a housing HOU disposed on the substrate SUB, the plurality of print heads PHD arranged inside the housing HOU, a plurality of nozzles NZ1, NZ2, and NZ3, and an ink supply device ISU. In some embodiments, the head assembly HU may be driven by a linear motor or guide-rail actuator to enable precise reciprocal movement in the first direction DR1 for uniform ink-droplet ejection.

The nozzles NZ1, NZ2, and NZ3 may be arranged on lower surfaces of the print heads PHD, respectively. The nozzles NZ1, NZ2, and NZ3 may include the plurality of first nozzles NZ1 arranged in the first direction DR1. The first nozzles NZ1 may be represented as a first nozzle group NZ1G. The nozzles NZ1, NZ2, and NZ3 may include the plurality of second nozzles NZ2 arranged in the first direction DR1. The second nozzles NZ2 may be represented as a second nozzle group NZ2G. The nozzles NZ1, NZ2, and NZ3 may include the plurality of third nozzles NZ3 arranged in the first direction DR1. The third nozzles NZ3 may be represented as a third nozzle group NZ3G. Each nozzle group NZ1G, NZ2G, NZ3G may correspond to a distinct ink composition or color, such as red, green, and blue, respectively, to facilitate multi-color patterning of the organic light-emitting layers.

The first nozzle group NZ1G, the second nozzle group NZ2G, and the third nozzle group NZ3G may be arranged in the second direction DR2 intersecting the first direction DR1. For example, the first nozzle group NZ1G, the second nozzle group NZ2G, and the third nozzle group NZ3G may be connected to the ink supply device ISU. FIGS. 6, 7A, and 7B illustrate the nozzles NZ1, NZ2, and NZ3 of the first nozzle group NZ1G, the second nozzle group NZ2G, and the third nozzle group NZ3G, but the numbers of the nozzles NZ1, NZ2, and NZ3 are not necessarily limited thereto as long as the nozzles NZ1, NZ2, and NZ3 are grouped. For example, additional nozzle rows or staggered arrays may be employed depending on required pixel density or pattern resolution.

The first nozzles NZ1 and the third nozzles NZ3 may be arranged in the corresponding same columns in the second direction DR2. The first nozzles NZ1 and the third nozzles NZ3 may partially or fully overlap each other in the second direction DR2. The second nozzles NZ2 may be arranged in columns between the columns in which the first nozzles NZ1 are arranged. For example, the second nozzles NZ2 might not overlap the first nozzles NZ1 and the third nozzles NZ3 in the second direction DR2. When viewed in the second direction DR2, the second nozzles NZ2 may be arranged between the first nozzles NZ 1 and the third nozzles NZ3. For example, the second nozzles NZ2 may overlap a portion of the first nozzles NZ1 and a portion of the third nozzles NZ3. In some cases, the first nozzles NZ 1, the second nozzles NZ2, and the third nozzles NZ3 may form a zigzag pattern in the plan view. This staggered configuration enables adjacent nozzle groups to cover different pixel rows without interference, and thus form uniform deposition of multiple ink materials across the substrate.

The ink supply device ISU may be connected to the print heads PHD. The ink supply device ISU may supply the ink INK (see FIG. 2) to the print heads PHD. The ink INK may be discharged from the nozzles NZ1, NZ2, and NZ3 through the ink supply device ISU. In some cases, the ink supply device ISU may include an internal pressure control system or pump that maintains a constant pressure level at the nozzle openings to ensure stable droplet formation during the printing operation.

The cleaning head CLH may include a first cleaning head portion CLHP1 and a second cleaning head portion CLHP2 spaced apart from each other in the first direction DR1. In some cases, each cleaning head portion may correspond to a nozzle group or array to enable targeted cleaning operations without cross-contamination between ink types.

The first cleaning head portion CLHP1 may be a position in which the cleaning head CLH overlaps the first nozzles NZ1, the third nozzles NZ3, and the recesses RCS in the plan view. In the first cleaning head portion CLHP1, the cleaning head CLH may move in the first direction DR1 and the second direction DR2 to remove residual ink or solvent and restore discharge stability of the first nozzles NZ1 and the third nozzles NZ3. In some cases, the movement path may be controlled by the actuators described with reference to FIG. 5A.

The second cleaning head portion CLHP2 may be a position in which the cleaning head CLH overlaps the second nozzles NZ2 and the recesses RCS in the plan view. In the second cleaning head portion CLHP2, the cleaning head CLH may move in the first direction DR1 and the second direction DR2 to remove residual ink or solvent and restore discharge stability of the second nozzles NZ2.

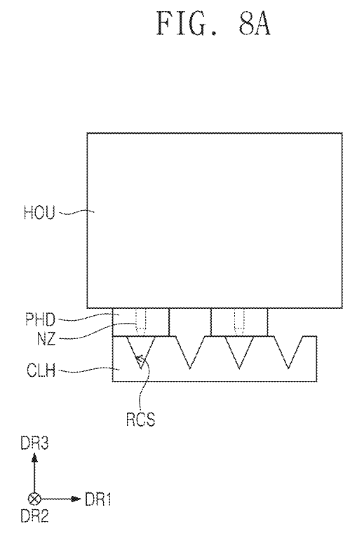

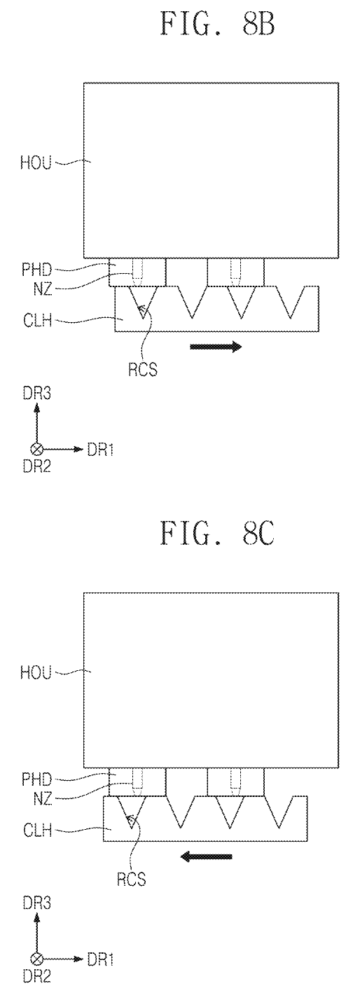

FIGS. 8A to 8C are cross-sectional views of the head assembly and a cleaning head according to an embodiment of the present disclosure. For convenience of description, in the head assembly HU, the housing HOU, the print heads PHD, and the nozzles NZ are illustrated schematically, and other structural components might not be illustrated for clarity. Referring to FIGS. 8A to 8C, the cleaning head CLH may move in the first direction DR1. The nozzles NZ may be arranged inside the print head PHD. A lowermost surface of the print head PHD in the third direction DR3 and a lowermost surface of the nozzles NZ in the third direction DR3 may be substantially aligned on the same plane. The cleaning head CLH may include a hygroscopic material that absorbs residual ink INK from the nozzle tips. While the cleaning head CLH reciprocates and vibrates in the first direction DR1, the remaining ink INK remaining in the nozzles NZ after a discharging process may be drawn into the recesses RCS of the cleaning head CLH through absorption. The cleaning head CLH may remove the remaining ink INK without directly contacting the nozzles NZ, and thus reducing or preventing damage to discharge portions of the nozzles NZ and avoiding blockage of the discharge portions of the nozzles NZ caused drying of the remaining ink INK. Further, since the cleaning is performed without mechanical contact, deterioration or peeling of water-repellent coating applied to the discharge portions of the nozzles NZ may be prevented.

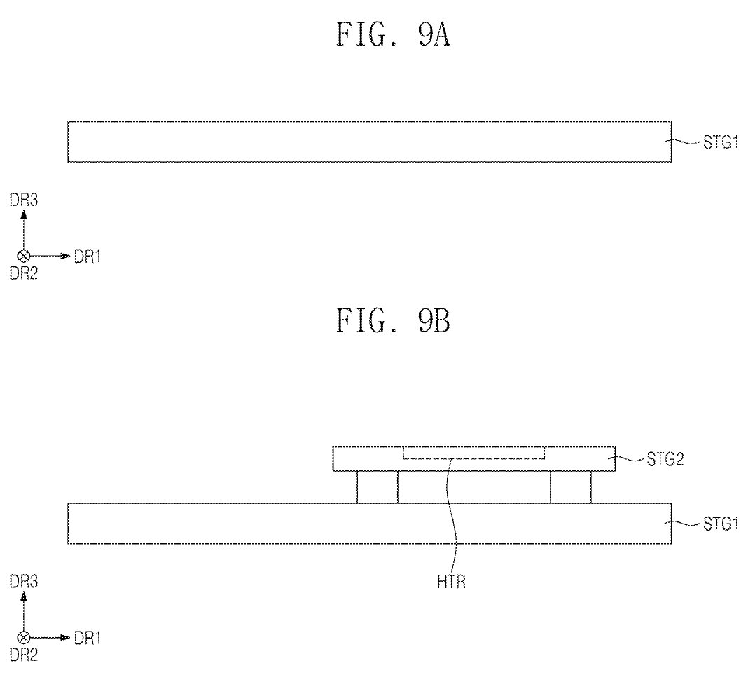

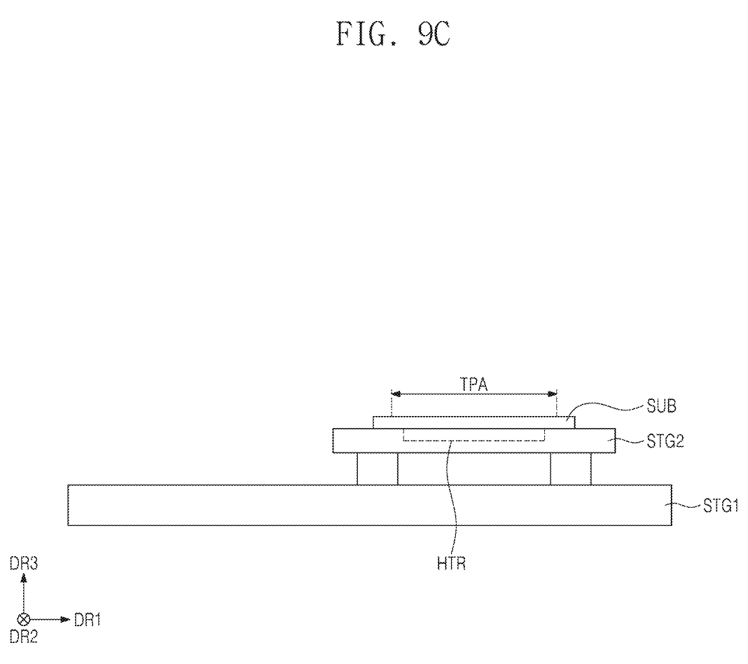

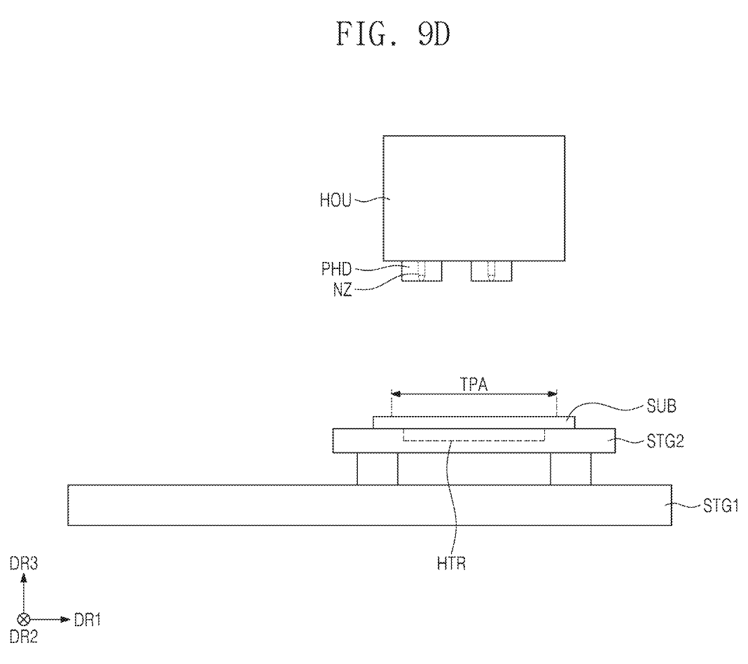

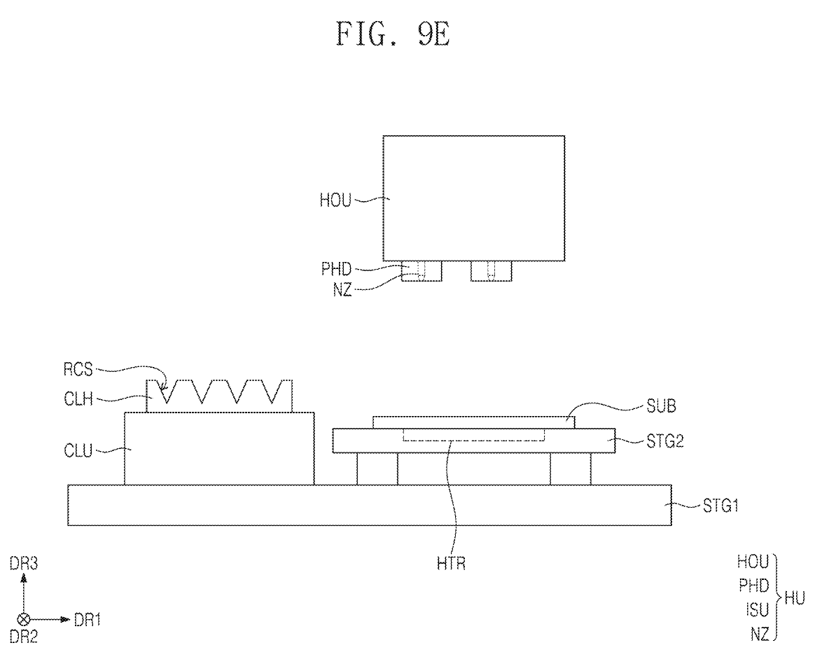

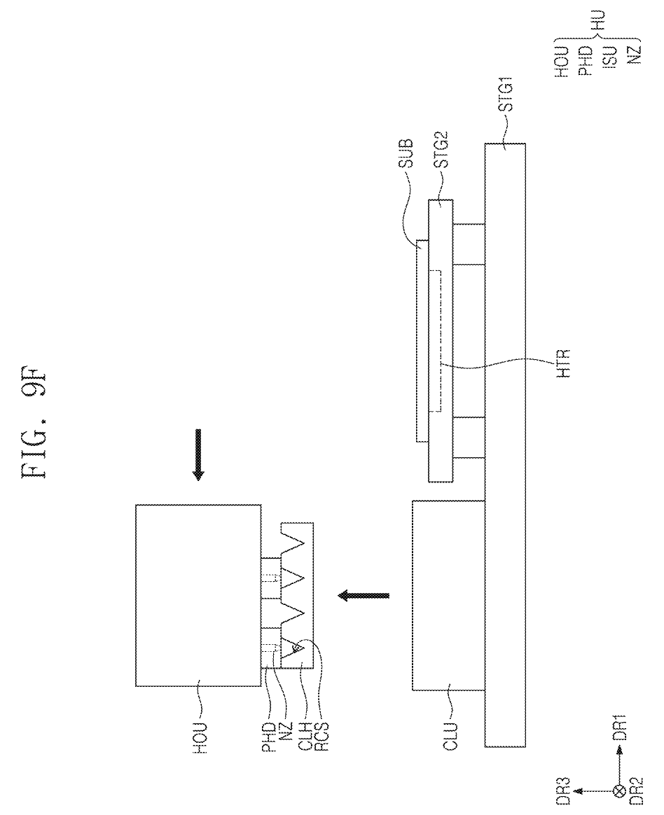

FIGS. 9A to 9F are schematic cross-sectional views illustrating a method for cleaning an inkjet printing apparatus according to an embodiment of the present disclosure.

For convenience of description, in FIGS. 9D and 9F, components of the head assembly HU other than the print heads PHD, the housing HOU, and the nozzles NZ might not be illustrated.

Referring to FIG. 9A, the method for cleaning an inkjet printing apparatus may include an operation of preparing the first stage STG1. For example, the method includes preparing a first stage STG1 configured to serve as a base or support platform for subsequent components.

Referring to FIG. 9B, the method for cleaning an inkjet printing apparatus may include an operation of arranging or disposing the second stage STG2 on the first stage STG1. The second stage STG2 may include the heater HTR disposed within or below an upper surface of the second stage STG2 to provide thermal energy during the drying process.

Referring to FIG. 9C, the method for cleaning an inkjet printing apparatus may include an operation of arranging the substrate SUB including the print area TPA that at least partially overlaps the heater HTR on the second stage STG2 in the plan view. The overlapping arrangement ensures uniform heat transfer to the print area TPA of the substrate SUB during drying or curing of ink droplets.

Referring to FIG. 9D, the method for cleaning an inkjet printing apparatus may include an operation of arranging the head assembly HU (see FIG. 5A) which moves in the first direction DR1 and includes the housing HOU disposed above the substrate SUB, the plurality of print heads PHD arranged inside the housing HOU, the plurality of nozzles NZ arranged on the lower surfaces of the print heads PHD, and the ink supply device ISU (see FIG. 5A) for supplying ink INK (see FIG. 5A) to the print heads PHD. The method for cleaning an inkjet printing apparatus may include an operation of discharging the ink INK toward the substrate SUB through the nozzles NZ to form a target organic light-emitting layer pattern.

Referring to FIG. 9E, the method for cleaning an inkjet printing apparatus may include an operation of arranging the cleaning assembly CLU that moves in the second direction DR2 intersecting the first direction DR1 on the first stage STG1. The method for cleaning an inkjet printing apparatus may include an operation of arranging the cleaning head CLH, which at least partially overlaps the nozzles NZ, on the cleaning assembly CLU and the cleaning head CLH includes a hygroscopic material for absorbing residual ink INK.

Referring to FIG. 9F, the head assembly HUI may move in the first direction DR1. The method for cleaning an inkjet printing apparatus may include an operation of moving the cleaning assembly CLU in the first direction DR1 to overlap the head assembly HU in the plan view. The method for cleaning an inkjet printing apparatus may include an operation of moving the cleaning assembly CLU in the second direction DR2 to overlap with the nozzle region of the head assembly HU in the plan view.

The method for cleaning an inkjet printing apparatus may include an operation of moving the cleaning head CLH in the third direction DR3 intersecting both the first direction DR1 and the second direction DR2. The cleaning head CLH may move in the third direction DR3 using the second frame FR2 (see FIG. 5A). The cleaning head CLH may move in the third direction DR3 so that the recesses RCS are positioned to overlap the nozzles NZ.

Referring to FIGS. 7B and 9F, the cleaning head CLH may include the first cleaning head portion CLHP1 that is disposed adjacent to lower surfaces of the first nozzles NZ1 and the third nozzles NZ3 and absorbs the residual ink INK (see FIG. 5A) remaining on the first nozzles NZ 1 and the third nozzles NZ3. The cleaning head CLH may include the second cleaning head portion CLHP2 that is disposed adjacent to lower surfaces of the second nozzles NZ2 and absorbs the residual ink INK (see FIG. 5A) remaining on the second nozzles NZ2. Each cleaning head portion may operate independently or sequentially to remove ink from the corresponding nozzle group.

Referring to FIG. 9F, the method for cleaning an inkjet printing apparatus may include an operation of positioning an upper surface of the cleaning head CLH on the lower surfaces of the print heads PHD. The method for cleaning an inkjet printing apparatus may include an operation of arranging the cleaning head CLH adjacent to the lower surfaces of the nozzles NZ. The method for cleaning an inkjet printing apparatus may include an operation of absorbing the ink INK (see FIG. 5A) remaining on the nozzles NZ through the cleaning head CLH. The method for cleaning an inkjet printing apparatus may further include an operation of bringing the cleaning head CLH into contact with the ink INK remaining on the nozzles NZ without mechanically contacting the nozzle surface.

The cleaning head CLH may move in the third direction DR3 and come into contact with the head assembly HU. Through this movement, the cleaning head CLH may begin to remove the residual ink INK (see FIG. 5A) present near the discharge portions of the nozzles NZ, thereby restoring optimal discharge performance and preventing clogging or drying-induced defects.

The method for cleaning the inkjet printing apparatus includes sequentially positioning and operating the first stage, the second stage including the integrated heater HTR, the substrate SUB, the head assembly HU, and the cleaning assembly CLU. During the cleaning cycle, the cleaning head CLH is aligned with the nozzles NZ based on coordinated movement in the first, second, and third directions DR1, DR2, and DR3. The cleaning head CLH, which includes hygroscopic recesses, absorbs residual ink remaining around the nozzle openings while the head reciprocates without direct contact. This non-contact absorption process effectively removes dried or excess ink, maintains nozzle cleanliness, and prevents clogging or degradation of the water-repellent surface.

According to the inkjet printing apparatus, a cleaning head may move in a first direction. The cleaning head may include a hygroscopic material, and while the cleaning head vibrates in the first direction, the remaining ink remaining in the nozzles after a process of discharging the ink INK (see FIG. 5A) by the nozzles NZ may be absorbed into the cleaning head. The cleaning head CLH may remove the remaining ink without direct contact with the nozzles, and thus damage to discharge portions of the nozzles and blockage of the discharge portions of the nozzles due to drying of the remaining ink may be reduced and removed. Further, damage to a water repellent material applied to the discharge portions of the nozzles may be prevented.

Although the description has been made above with reference to an embodiment of the present disclosure, it may be understood that those skilled in the art or those having ordinary knowledge in the art may variously modify and change the present disclosure without departing from the spirit and technical scope of the present disclosure described in the appended claims.

What is claimed is:

1. An inkjet printing apparatus comprising:
a first stage;
a second stage including a heater disposed on the first stage, wherein the second stage is configured to support a substrate including a print area overlapping the heater;
a head assembly disposed over the substrate, wherein the head assembly is configured to move in a first direction parallel to an upper surface of the first stage and includes a housing, a plurality of print heads disposed inside the housing, a plurality of nozzles disposed inside the plurality of print heads, respectively, and an inkjet supply device configured to supply an ink to the plurality of print heads; and
a cleaning assembly disposed on the first stage and configured to move in a second direction intersecting the first direction; and
wherein cleaning assembly includes a cleaning head including a hygroscopic material and configured to move in the first direction and the second direction, and including a plurality of recesses at least partially overlapping the nozzles.

2. The inkjet printing apparatus of claim 1, wherein the nozzles include:
a plurality of first nozzles formed as a first nozzle group and spaced apart in the first direction;
a plurality of second nozzles formed as a second nozzle group and spaced apart in the first direction; and
a plurality of third nozzles formed as a third nozzle group and spaced apart in the first direction.

3. The inkjet printing apparatus of claim 2, wherein the first nozzle group, the second nozzle group, and the third nozzle group are spaced apart in the second direction.

4. The inkjet printing apparatus of claim 2, wherein the first nozzles and the third nozzles are arranged in same columns in the second direction.

5. The inkjet printing apparatus of claim 4, wherein the first nozzles, the second nozzles, and the third nozzles are arranged in a zigzag pattern.

6. The inkjet printing apparatus of claim 2, wherein the cleaning head includes:
a first cleaning head portion overlapping the first nozzles, the third nozzles, and the recesses.

7. The inkjet printing apparatus of claim 2, wherein the cleaning head includes:
a second cleaning head portion overlapping the second nozzles and the recesses.

8. The inkjet printing apparatus of claim 1, wherein:
the second stage further includes an adsorption hole.

9. The inkjet printing apparatus of claim 1, further comprising:
a first frame connecting the first stage and the head assembly.

10. The inkjet printing apparatus of claim 1, further comprising:
a second frame disposed on the cleaning assembly and connecting the cleaning assembly and the cleaning head.

11. A method for cleaning an inkjet printing apparatus, the method comprising:
preparing a first stage;
disposing a second stage including a heater on the first stage;
disposing a substrate including a print area overlapping the heater on the second stage;
disposing a head assembly including a plurality of nozzles on the substrate;
discharging an ink onto the substrate through the plurality of nozzles;
arranging a cleaning head adjacent to lower surfaces of the plurality of nozzles; and
absorbing the ink remaining in the nozzles through the cleaning head.

12. The method of claim 11, wherein:
the head assembly is configured to move in a first direction parallel to an upper surface of the first stage,
wherein the head assembly further includes:
a housing;
a plurality of print heads disposed inside the housing; and
an ink supply device configured to supply the ink to the plurality of print heads, and
wherein the nozzles are arranged inside the plurality of print heads, respectively.

13. The method of claim 11, wherein arranging the cleaning head includes:
arranging the cleaning head adjacent to the lower surfaces of the nozzles by moving the cleaning head in a first direction, a second direction intersecting the first direction, and a third direction intersecting a plane defined by the first direction and the second direction.

14. The method of claim 13, further comprising:
disposing a cleaning assembly configured to move the cleaning head in the first direction and the second direction under the cleaning head.

15. The method of claim 13, wherein:
the cleaning head includes a hygroscopic material, and includes a plurality of recesses overlapping portions of the nozzles.

16. The method of claim 15, further comprising:
positioning the cleaning head into contact with the ink remaining on the nozzles.

17. The method of claim 11, wherein the nozzles include:
a plurality of first nozzles formed as a first nozzle group and spaced apart in a first direction;
a plurality of second nozzles formed as a second nozzle group and spaced apart in the first direction; and
a plurality of third nozzles formed as a third nozzle group and spaced apart in the first direction, and
wherein the first nozzle group, the second nozzle group, and the third nozzle group are spaced apart in a second direction intersecting the first direction.

18. The method of claim 17, wherein the cleaning head includes:
a first cleaning head portion disposed adjacent to lower surfaces of the first nozzles and the third nozzles, and configured to absorb an ink remaining on the first nozzles and the third nozzles; and
a second cleaning head portion disposed adjacent to lower surfaces of the second
nozzles, and configured to absorb an ink remaining on the second nozzles.

19. An electronic device comprising:
a display device including a pixel manufactured using an inkjet printing apparatus; and a processor configured to transmit an image data signal and an input control signal to the display device,
wherein the inkjet printing apparatus comprises:
a first stage;
a second stage including a heater disposed on the first stage, wherein the second stage is configured to support a substrate including a print area overlapping the heater;
a head assembly disposed over the substrate, wherein the head assembly is configured to move in a first direction parallel to an upper surface of the first stage and includes a housing, a plurality of print heads disposed inside the housing, a plurality of nozzles disposed inside the plurality of print heads, respectively, and an inkj et supply device configured to supply an ink to the plurality of print heads; and
a cleaning assembly disposed on the first stage and configured to move in a second direction intersecting the first direction; and
wherein the cleaning assembly includes a cleaning head including a hygroscopic material and configured to move in the first direction and the second direction, and including a plurality of recesses at least partially overlapping the nozzles.

20. The electronic device of claim 19, wherein the nozzles include:
a plurality of first nozzles formed as a first nozzle group and spaced apart in the first direction;
a plurality of second nozzles formed as a second nozzle group and spaced apart in the first direction; and
a plurality of third nozzles formed as a third nozzle group and spaced apart in the first direction,
wherein the first nozzles, the second nozzles, and the third nozzles are arranged in a zigzag pattern.
